(19) United States
(12) Patent Application Publication
(10) Pub. No.: US 2014/0290982 A1
(43) Pub. Date: Oct. 2, 2014

(54) PRINTED CIRCUIT BOARD AND METHOD FOR MANUFACTURING THE SAME

(71) Applicant: SAMSUNG ELECTRO-MECHANICS CO., LTD., Suwon-si (KR)

(72) Inventors: Dong Uk Lee, Suwon-si (KR); Young Gon Kim, Suwon-si (KR); Seung Hyun Noh, Suwon-si (KR)

(73) Assignee: SAMSUNG ELECTRO-MECHANICS CO., LTD., Suwon-si (KR)

(21) Appl. No.: 14/208,752

(22) Filed: Mar. 13, 2014

(30) Foreign Application Priority Data
Mar. 28, 2013 (KR) 10-2013-0033612

(51) Int. Cl. H05K 1/02; H05K 3/46

(52) U.S. Cl. CPC H05K 1/02; H05K 3/4644
USPC 174/250; 29/846

(57) ABSTRACT

Disclosed herein is a printed circuit board including: an insulating layer having first and second surfaces; a first circuit layer formed on the first surface of the insulating layer and including at least one first circuit pattern; a second circuit layer formed on the first circuit layer and including at least one second circuit pattern; and an insulating film formed in an insulating region of the first and second circuit layers.

### CROSS REFERENCE TO RELATED APPLICATION

This application claims the benefit of Korean Patent Application No. 10-2013-0033612, filed on Mar. 28, 2013, entitled “Printed Circuit Board and Method for Manufacturing the Same”, which is hereby incorporated by reference in its entirety into this application.

### BACKGROUND OF THE INVENTION

1. Technical Field

The present invention relates to a printed circuit board and a method for manufacturing the same.

2. Description of the Related Art

A printed circuit board is a board electrically connecting a plurality of components to electric and electronic devices to allow the components electrically connected to each other to exchange power or an electric signal with each other. The printed circuit board has been widely used throughout electric and electronic devices such as a cellular phone, a laptop computer, a display apparatus, and the like.

An example of the printed circuit board includes a single-sided printed circuit board in which a circuit layer is formed only on one surface of a base substrate, a double-sided printed circuit board in which circuit layers are formed on both surfaces of the base substrate, and a multilayer printed circuit board in which multiple circuit layers are formed on the base substrate. Generally, the base substrate includes the circuit layers formed thereon and an insulating layer burying the circuit layer therein. The circuit layers and the insulating layers are repeatedly stacked, such that a multi-layer printed circuit board is formed (U.S. Pat. No. 5,837,427). In this configuration, at the time of connecting patterns of one circuit layer to each other, since the patterns should be designed to be spaced apart from each other by any interval in order to be electrically insulated from each other, a board requires a wide area

### SUMMARY OF THE INVENTION

The present invention has been made in an effort to provide a printed circuit board capable of decreasing a design area, and a method for manufacturing the same.

Further, the present invention has been made in an effort to provide a printed circuit board having an improved degree of freedom in a design, and a method for manufacturing the same.

Further, the present invention has been made in an effort to provide a printed circuit board having a stable two-layer structure, and a method for manufacturing the same.

According to a preferred embodiment of the present invention, there is provided a printed circuit board including: an insulating layer having first and second surfaces; a first circuit layer formed on the first surface of the insulating layer and including at least one first circuit pattern; a second circuit layer formed on the first circuit layer and including at least one second circuit pattern; and an insulating film formed in an insulating region of the first and second circuit layers.

The insulating film may be formed to enclose the first circuit pattern in the insulating region.

The first circuit layer may be formed on the first surface of the insulating layer.

The first circuit layer may further include first and second connection patterns.

The second circuit pattern may electrically connect the first and second connection patterns to each other.

The first circuit layer may be buried in the first surface of the insulating layer and be formed so that an upper surface thereof is exposed to the outside of the first surface of the insulating layer.

The printed circuit board may further include a first solder resist formed on the first surface of the insulating layer, the first circuit layer, and the second circuit layer.

The second circuit pattern may intersect with the first circuit pattern in the insulating region.

The second circuit pattern may have a lower surface contacting the first surface of the insulating layer.

The printed circuit board may further include a third circuit layer formed on the second surface of the insulating layer and including at least one third circuit pattern.

The printed circuit board may further include a second solder resist formed on the second surface of the insulating layer and the third circuit layer.

The printed circuit board may further include at least one internal circuit layer formed in the insulating layer.

According to another preferred embodiment of the present invention, there is provided a printed circuit board including: an insulating layer having first and second surfaces; a first circuit layer buried in the first surface of the insulating layer, including at least one first circuit pattern, and formed so that an upper surface thereof is exposed to the outside of the first surface of the insulating layer; a second circuit layer formed on the first circuit layer and including at least one second circuit pattern; and an insulating film formed in an insulating region of the first and second circuit layers.

The insulating film may be formed to enclose the first circuit pattern in the insulating region.

The second circuit pattern may have a lower surface contacting the first surface of the insulating layer.

The printed circuit board may further include a third circuit layer formed on the second surface of the insulating layer and including at least one third circuit pattern.

According to still another preferred embodiment of the present invention, there is provided a method for manufacturing a printed circuit board, including: preparing an insulating layer having first and second surfaces; forming a first circuit layer on the first surface of the insulating layer, the first circuit layer including at least one first circuit pattern; forming an insulating film so as to enclose the first circuit pattern in the insulating region; and forming a second circuit layer formed on the insulating film, the second circuit layer including at least one second circuit pattern.

In the forming of the insulating film, the insulating film may be formed over the first circuit pattern on which the second circuit pattern is stacked in the insulating region.

In the forming of the insulating film, the insulating film may be formed by an inkjet printing method.

The forming of the second circuit layer may include: forming a seed layer on the first surface of the insulating layer and the first circuit layer by an electroless plating method; forming a plating resist having an opening part formed therein so that a region of the second circuit pattern is opened; performing electroplating on the opening part to form the second circuit pattern; removing the plating resist; and removing the seed layer exposed to the outside by the removed plating resist.

The first circuit layer may be formed on the first surface of the insulating layer.

The first circuit layer may be formed to be buried in the first surface of the insulating layer and be formed so that an upper surface thereof is exposed to the outside of the first surface of the insulating layer.

The method may further include, after the forming of the second circuit layer, forming a first solder resist on the first surface of the insulating layer, the first circuit layer, and the second circuit layer.

The method may further include forming a third circuit layer on the second surface of the insulating layer at the time of forming the first circuit layer, the third circuit layer including a third circuit pattern.

The method may further include, after the forming of the third circuit layer, forming a second solder resist on the second surface of the insulating layer and beneath the third circuit layer.

In the forming of the first circuit layer, the first circuit layer may further include first and second connection patterns.

In the forming of the second circuit pattern, the second circuit pattern may be formed to electrically connect the first and second connection patterns to each other.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view showing a printed circuit board according to a preferred embodiment of the present invention;

FIG. 2 is a cross-sectional view showing the printed circuit board according to the preferred embodiment of the present invention;

FIGS. 3 to 9 are views showing a method for manufacturing a printed circuit board according to the preferred embodiment of the present invention;

FIG. 10 is a perspective view showing a printed circuit board according to another preferred embodiment of the present invention;

FIG. 11 is a cross-sectional view showing the printed circuit board according to another preferred embodiment of the present invention;

FIGS. 12 to 18 are views showing a method for manufacturing a printed circuit board according to another preferred embodiment of the present invention; and

FIG. 19 is a plan view showing a printed circuit board according to another embodiment.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

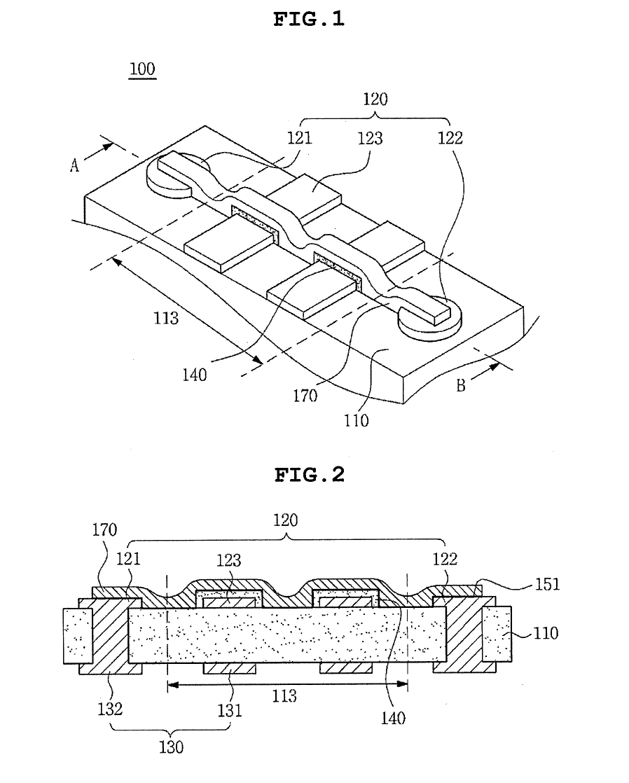

FIG. 1 is a perspective view showing a printed circuit board according to a preferred embodiment of the present invention.

Referring to FIG. 1, the printed circuit board 100 may include an insulating layer 110, a first circuit layer 120, a second circuit pattern 170, and an insulating film 140.

The insulating layer 110 may be made of a composite polymer resin generally used as an interlayer insulating material. For example, the insulating layer 110 may be made of a prepreg, Ajinomoto Build up Film (ABF), or an epoxy based resin such as FR-4, Bismaleimide Triazine (BT), or the like. In addition, the insulating layer 110 may have a form of a substrate or a film. However, in the preferred embodiment of the present invention, a material and a form of the insulating layer 110 are not limited thereto.

The insulating layer 110 may include an insulating region 113. The insulating region 113 may be formed so that the first circuit layer 120 and the second circuit pattern 170 intersect with each other and be a region in which the first circuit layer 120 and the second circuit pattern 170 are electrically insulated from each other.

The first circuit layer 120 may be formed on the insulating layer 110. The first circuit layer 120 may include a first connection pattern 121, a second connection pattern 122, and a first circuit pattern 123.

The first and second connection patterns 121 and 122 may be components electrically connected to each other. The first and second connection patterns 121 and 122 may be pads of vias (not shown) formed in the insulating layer 110, respectively. Alternatively, the first and second connection patterns 121 and 122 may be general patterns. As described above, the first and second connection patterns 121 and 122 may be any components electrically connected to each other.

The first circuit pattern 123 may be formed for electrical connection between other components that are not shown in FIG. 1. Alternatively, the first circuit pattern 123 may be an individual pattern.

The second circuit layer may include the second circuit pattern 170. The second circuit pattern 170 may electrically connect the first and second connection patterns 121 and 122 to each other. The second circuit pattern 170 may be stacked in a form in which it intersects with the first circuit pattern 123 over the first circuit pattern 123 as shown in FIG. 1 when it electrically connects the first and second connection patterns 121 and 122 to each other. Here, the second circuit pattern 170 and the first circuit pattern 123 may be formed to intersect with each other in the insulating region 113.

According to the preferred embodiment of the present invention, the first circuit layer 120 and the second circuit layer may be made of a conductive metal. Here, the conductive metal may be any metal usually used for a circuit pattern, such as copper, nickel, gold, or the like.

The insulating film 140 may be formed between the first and second circuit patterns 123 and 170. The insulating film 140 may be formed in the insulating region 113 of the insulating layer 110. That is, the insulating film 140 may be formed at a position at which the first and second circuit patterns 123 and 170 intersect with each other to electrically insulate the first and second circuit patterns 123 and 170 from each other. The insulating film 140 may be made of a general interlayer insulating material, similar to the insulating layer 110. For example, the insulating film 140 may be made of a prepreg, Ajinomoto Build up Film (ABF), or an epoxy based resin such as FR-4, Bismaleimide Triazine (BT), or the like.

According to the preferred embodiment of the present invention, the second circuit pattern 170 may be formed to intersect with the first circuit pattern 123 over the first circuit pattern 123 when the first and second connection patterns 121 and 122 are electrically connected to each other. Therefore, an area may be decreased as compared with the prior art in which the first and second circuit patterns 123 and 170 are formed to be spaced apart from each other without being overlapped with each other. In addition, the second circuit pattern 170 is insulated from the first circuit pattern 123 by the insulating film 140, such that a restriction for a position at which the second circuit pattern 170 is formed is decreased, thereby making it possible to increase a degree of freedom in a design. That is, the first circuit layer 120 and the second circuit pattern 170 may be freely connected to each other.

According to the preferred embodiment of the present invention, although not shown, a solder resist for protecting the first circuit layer 120 and the second circuit pattern 170 may be further formed. It is obvious to those skilled in the art that a circuit layer and a solder resist may be further formed on the other surface of the insulating layer 110 as well as one surface of the insulating layer 110 on which the first circuit layer 120 is formed.

FIG. 2 is a cross-sectional view showing the printed circuit board according to the preferred embodiment of the present invention.

FIG. 2 is a view showing a cross section taken along the line A-B of the printed circuit board 100 shown in FIG. 1.

Referring to FIG. 2, the printed circuit board 100 may include the insulating layer 110, the first circuit layer 120, the second circuit pattern 170, a third circuit layer 130, and the insulating film 140.

The insulating layer 110 may be formed to have first and second surfaces 111 and 112. The insulating layer 110 may be made of a composite polymer resin generally used as an interlayer insulating material. For example, the insulating layer 110 may be made of a prepreg, Ajinomoto Build up Film (ABF), or an epoxy based resin such as FR-4, Bismaleimide Triazine (BT), or the like. In addition, the insulating layer 110 may have a form of a substrate or a film. However, in the preferred embodiment of the present invention, a material and a form of the insulating layer 110 are not limited thereto.

The insulating layer 110 may include the insulating region 113. The insulating region 113 may be formed so that the first circuit layer 120 and the second circuit pattern 170 intersect with each other and be a region in which the first circuit layer 120 and the second circuit pattern 170 are electrically insulated from each other.

The first circuit layer 120 may be formed on the first surface 111 of the insulating layer 110. The first circuit layer 120 formed on the insulating layer 110 may include the first connection pattern 121, the second connection pattern 122, and the first circuit pattern 123. Here, the first and second connection patterns 121 and 122 may be components electrically connected to each other by the first circuit pattern 123 or the second circuit pattern 170. As shown, the first and second connection patterns 121 and 122 may be pads of first and second vias 115 and 116 formed in the insulating layer 110, respectively. However, this is only an example. That is, the first and second connection patterns 121 and 122 are not limited to being the pads of the vias. That is, the first and second connection patterns 121 and 122 may be any patterns electrically connected to each other.

The second circuit layer may include the second circuit pattern 170. The second circuit pattern 170 may be formed on the first surface 111 of the first insulating layer 110 and the first circuit pattern 123. Here, the second circuit pattern 170 may be formed so that one end thereof contacts the first connection pattern 121. In addition, the second circuit pattern 170 may be formed so that the other end thereof contacts the second connection pattern 122. The second circuit pattern 170 formed as described above may electrically connect the first and second connection patterns 121 and 122 to each other.

The insulating film 140 may be formed in the insulating region 113 of the insulating layer 110. In addition, the insulating film 140 may be formed between the first and second circuit patterns 123 and 170. That is, the insulating film 140 may be formed at a position at which the first and second circuit patterns 123 and 170 intersect with each other to electrically insulate the first and second circuit patterns 123 and 170 from each other. The insulating film 140 may be formed to enclose the first circuit pattern 123 in a region in which the second circuit pattern 170 intersects with the first circuit pattern 123. The insulating film 140 may not be formed on the first circuit pattern 123 in a region in which the first and second circuit patterns 123 and 170 do not intersect with each other.

The insulating film 140 may be made of a general interlayer insulating material, similar to the insulating layer 110. For example, the insulating film 140 may be made of a prepreg, Ajinomoto Build up Film (ABF), or an epoxy based resin such as FR-4, Bismaleimide Triazine (BT), or the like.

The third circuit layer 130 may include at least one third circuit pattern 131 and a third connection pattern 132. The third connection pattern 132 may not only be a general circuit pattern, but also be pads of the first and second vias 115 and 116 formed in the insulating layer 110.

According to the preferred embodiment of the present invention, the first circuit layer 120, the second circuit layer, and the third circuit layer 130 may be made of a conductive metal. Here, the conductive metal may be any metal usually used for a circuit pattern, such as copper, nickel, gold, or the like.

Although not shown in FIG. 1, the printed circuit board 100 according to the preferred embodiment of the present invention may further include first and second solder resists 181 and 182. The first and second solder resists 181 and 182 may be formed in order to protect the first circuit layer 120, the second circuit pattern 170, and the third circuit layer 130. In addition, the first and second solder resists 181 and 182 may have opening parts formed therein so that regions for connection to the outside are opened. The first and second solder resists 181 and 182 may be made of a general heat resistant coating material.

Although the case in which the third circuit layer 130 is formed on the second surface 112 of the insulating layer 110 is shown in the preferred embodiment of the present invention, the present invention is not limited thereto. That is, circuit patterns stacked to intersect with each other, such as the first circuit layer 120 and the second circuit pattern 170 formed on the first surface 111 of the insulating layer 110 may also be formed on the second surface 112 of the insulating layer 110.

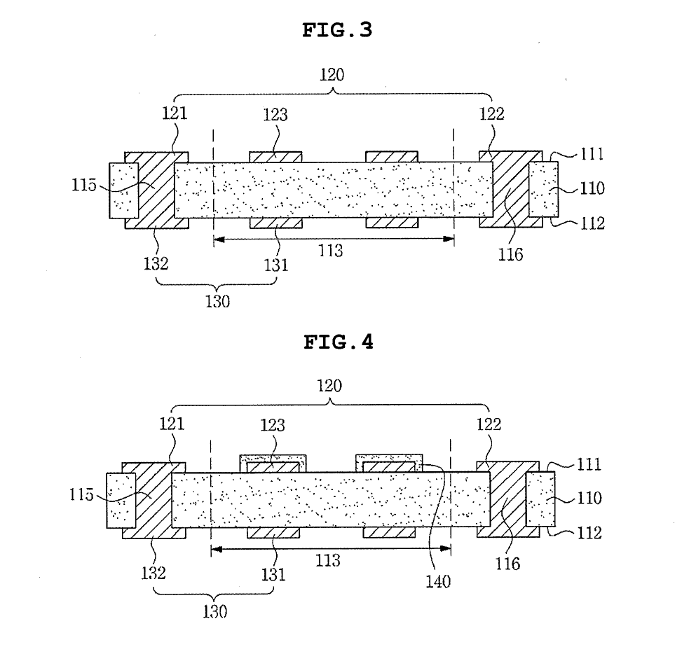

FIGS. 3 to 9 are views showing a method for manufacturing a printed circuit board according to the preferred embodiment of the present invention.

Referring to FIG. 3, the insulating layer 110 is provided. The insulating layer 110 may be formed to have the first and second surfaces 111 and 112. The insulating layer 110 may be made of a composite polymer resin generally used as an interlayer insulating material. For example, the insulating layer 110 may be made of a prepreg, Ajinomoto Build up Film (ABF), or an epoxy based resin such as FR-4, Bismaleimide Triazine (BT), or the like. In addition, the insulating layer 110 may have a form of a substrate or a film. However, in the preferred embodiment of the present invention, a material and a form of the insulating layer 110 are not limited thereto.

The insulating layer 110 may include an insulating region 113. The insulating region 113 may be formed so that the first circuit layer 120 and the second circuit pattern 170 intersect with each other and be a region in which the first circuit layer 120 and the second circuit pattern 170 are electrically insulated from each other.

The insulating layer 110 may have the first circuit layer 120 formed on the first surface 111 thereof. The first circuit layer 120 formed on the insulating layer 110 may include the first connection pattern 121, the second connection pattern 122, and the first circuit pattern 123. Here, the first and second connection patterns 121 and 122 may be components electrically connected to each other by the first circuit pattern 123 or the second circuit pattern 170. As shown, the first and second connection patterns 121 and 122 may be the pads of the first and second vias 115 and 116 formed in the insulating layer 110, respectively. However, this is only an example. That is, the first and second connection patterns 121 and 122 are not limited to being the pads of the vias. That is, the first and second connection patterns 121 and 122 may be any patterns electrically connected to each other.

The insulating layer 110 may have the third circuit layer 130 formed on the second surface 112 thereof. The third circuit layer 130 may include at least one third circuit pattern 131 and the third connection pattern 132. The third connection pattern 132 may not only be a general circuit pattern, but also be pads of the first and second vias 115 and 116 formed in the insulating layer 110.

The first and third circuit layers 120 and 130 may be formed by a semi-additive process (SAP) and a modified semi-additive process (MSAP). However, the first and third circuit layers 120 and 130 are not limited to being formed by the above-mentioned process, but may also be formed by any one of general circuit pattern forming methods.

Referring to FIG. 4, the insulating film 140 may be formed on the first circuit pattern 123. The insulating film 140 may be formed in the insulating region 113 of the insulating layer 110. In addition, the insulating film 140 may be formed to enclose the first circuit pattern 123. The insulating film 140 may be made of a general interlayer insulating material, similar to the insulating layer 110. For example, the insulating film 140 may be made of a prepreg, Ajinomoto Build up Film (ABF), or an epoxy based resin such as FR-4, Bismaleimide Triazine (BT), or the like. The insulating film 140 may be formed by an inkjet printing method. That is, the insulating film 140 may be formed by applying a liquid-phase insulating material onto the first circuit pattern 123 using an inkjet. The inkjet printing method as described above is only an example, and a method of forming the insulating film 140 is not limited thereto. The insulating film 140 may be formed by any method of applying a general insulating material as well as the inkjet printing method. Although not shown, the insulating film 140 may not be formed on the first circuit pattern 123 in a region in which the first circuit pattern 123 and a second circuit pattern 170 to be subsequently formed do not intersect with each other.

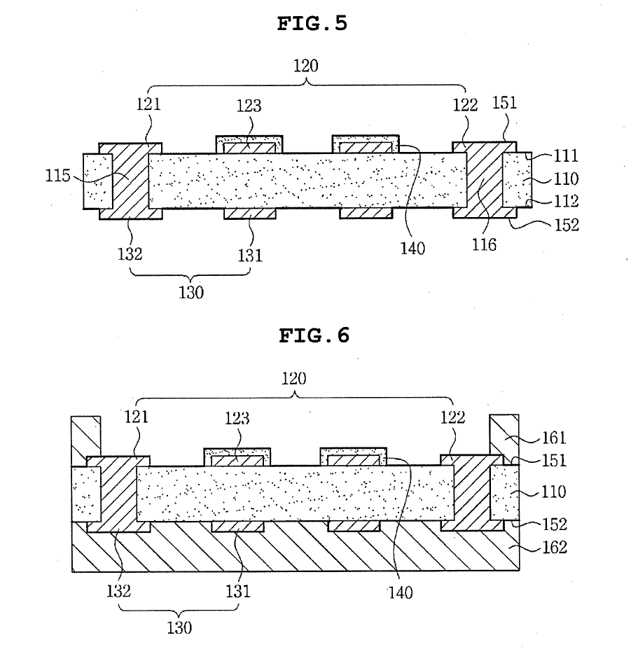

Referring to FIG. 5, first and second seed layers 151 and 152 may be formed. The first seed layer 151 may be formed on the first surface 111 of the insulating layer 110 and the first circuit layer 120. The second seed layer 152 may be formed on the second surface 112 of the insulating layer 110 and the third circuit layer 130. The first and second seed layers 151 and 152 may be made of a general electrical conductive material used for forming seed layers. For example, the first and second seed layers 151 and 152 may be made of at least one selected from a group consisting of copper, nickel, gold, silver, zinc, palladium, ruthenium, rhodium, lead, and tin. Here, the first seed layer 151 may be formed on the first connection pattern 121, the second connection pattern 122, and the insulating film 140. Here, the first seed layer 151 may be electrically connected to the first and second connection patterns 121 and 122. However, the first seed layer 151 may be in a state in which it is insulated from the first circuit pattern 123 by the insulating film 140.

Although both of the first and second seed layers 151 and 152 are formed in the preferred embodiment of the present invention, the present invention is not limited thereto. That is, an operation of forming the second seed layer 152 may be omitted by selection of those skilled in the art.

The first and second seed layers 151 and 152 may be formed by an electroless plating method. However, a method of forming the first and second seed layers 151 and 152 is not limited to the electroless plating method. The first and second seed layers 151 and 152 may be formed by a general depositing method. For example, the first and second seed layers 151 and 152 may be formed by a dry plating method such as a sputtering method as well as a wet plating method such as the electroless plating method.

Referring to FIG. 6, a first plating resist 161 may be formed on the first seed layer 151. The first plating resist 161 may have an opening part patterned therein so that a region in which the second circuit pattern 170 is to be formed on the first seed layer 151 is opened.

A second plating resist 162 may be formed on the second seed layer 152. In this configuration, since a circuit pattern is not formed on the second seed layer 152, the second plating resist 162 may be formed on the entire second seed layer 152. As another example, when the circuit pattern is formed on the second seed layer 152, the second plating resist 162 may also have an opening part patterned therein.

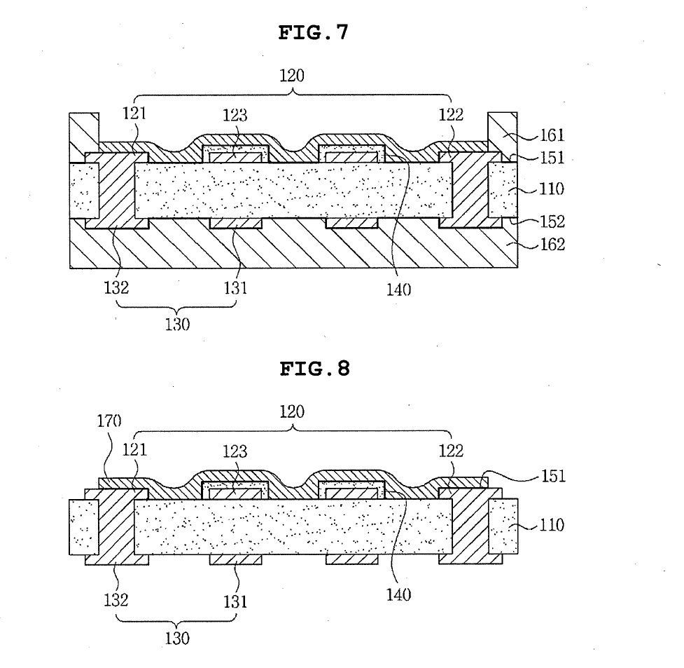

Referring to FIG. 7, the second circuit pattern 170, which is a second circuit layer, may be formed. The second circuit pattern 170 may be formed in the opening part of the second plating resist 162 by an electroplating method. Here, the second circuit pattern 170 may be formed by any method of forming a general circuit pattern as well as the electroplating method. The second circuit pattern 170 may be made of an electrical conductive material used for forming a circuit pattern. For example, the second circuit pattern 170 may be made of at least one selected from a group consisting of copper, nickel, gold, silver, zinc, palladium, ruthenium, rhodium, lead, and tin.

The second circuit pattern 170 formed as described above may be formed on the first circuit layer 120. The second circuit pattern 170 may be formed so that one end thereof contacts the first connection pattern 121. In addition, the second circuit pattern 170 may be formed so that the other end thereof contacts the second connection pattern 122. The second circuit pattern 170 formed as described above may electrically connect the first and second connection patterns 121 and 122 to each other. Here, the second circuit pattern 170 formed on the first circuit pattern 123 may be in a state in which it is insulated from the first circuit pattern 123 by the insulating film 140.

Referring to FIG. 8, the first and second plating resists 161 and 162 may be removed. In addition, the first seed layer 151 exposed by removing the first plating resist 161 may be removed. Further, the second seed layer 152 exposed by removing the second plating resist 162 may be removed. A method of removing the first and second seed layers 151 and 152 is not particularly limited. That is, the first and second seed layers 151 and 152 may be removed by a general method well-known in the art. For example, the first and second seed layers 151 and 152 may be removed by a quick etching method using a strong base such as NaOH or KOH. In addition, the first and second seed layers 151 and 152 may be removed by a flash etching method.

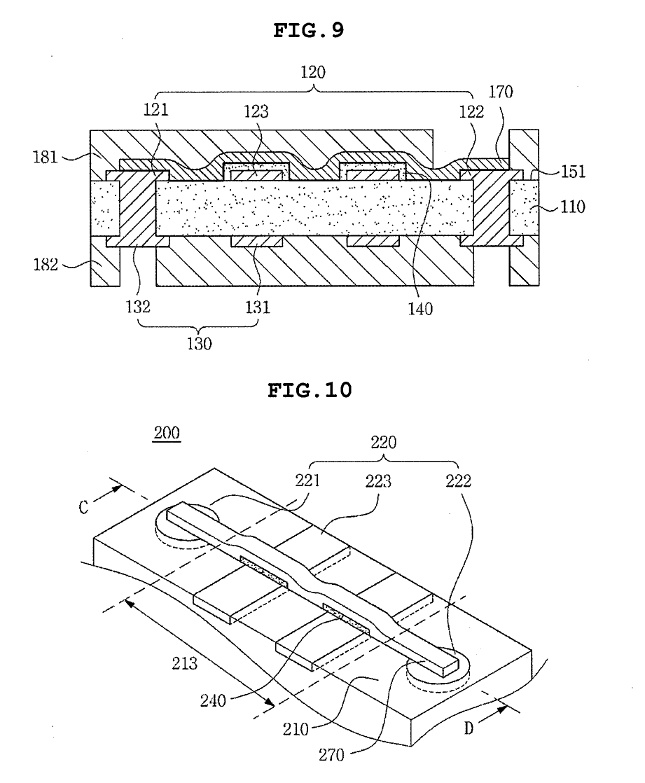

Referring to FIG. 9, the first and second solder resists 181 and 182 may be formed. The first solder resist 181 may be formed in order to protect the first circuit layer 120 and the second circuit pattern 170. The second solder resist 182 may be formed in order to protect the third circuit layer 130. In addition, the first and second solder resists 181 and 182 may have opening parts formed therein so that regions for connection to the outside are opened. The first and second solder resists 181 and 182 may be made of a general heat resistant coating material.

FIG. 10 is a perspective view showing a printed circuit board according to another preferred embodiment of the present invention.

Referring to FIG. 10, the printed circuit board 200 may include an insulating layer 210, a first circuit layer 220, a second circuit pattern 270, and an insulating film 240.

The insulating layer 210 may be made of a composite polymer resin generally used as an interlayer insulating material. For example, the insulating layer 210 may be made of a prepreg, Ajinomoto Build up Film (ABF), or an epoxy based resin such as FR-4, Bismaleimide Triazine (BT), or the like. In addition, the insulating layer 210 may have a form of a substrate or a film.

The insulating layer 210 may include an insulating region 213. The insulating region 213 may be formed so that the first circuit layer 220 and the second circuit pattern 270 intersect with each other and be a region in which the first circuit layer 220 and the second circuit pattern 270 are electrically insulated from each other.

The first circuit layer 220 may be formed in the insulating layer 210. According to another preferred embodiment of the present invention, the first circuit layer 220 may be formed to be buried in a first surface 211 of the insulating layer 210. Here, the first circuit layer 220 may be formed so that an upper surface thereof is exposed to the outside of the first surface 211 of the insulating layer 210.

The first circuit layer 220 may include a first connection pattern 221, a second connection pattern 222, and a first circuit pattern 223.

The first and second connection patterns 221 and 222 may be components electrically connected to each other. The first and second connection patterns 221 and 222 may be pads of vias (not shown) formed in the insulating layer 210, respectively. Alternatively, the first and second connection patterns 221 and 222 may be general circuit patterns. As described above, the first and second connection patterns 221 and 222 may be any components electrically connected to each other.

The first circuit pattern 223 may be formed for electrical connection between other components that are not shown in FIG. 10. Alternatively, the first circuit pattern 223 may be an individual pattern.

The second circuit layer may include the second circuit pattern 270. The second circuit pattern 270 may electrically connect the first and second connection patterns 221 and 222 to each other. The second circuit pattern 270 may be formed so that it partially intersects with the first circuit pattern 223.

The first circuit layer 220 and the second circuit layer may be made of a conductive metal. Here, the conductive metal may be any metal usually used for a circuit pattern, such as copper, nickel, gold, or the like.

The insulating film 240 may be formed in the insulating region 213 of the insulating layer 210. In addition, the insulating film 240 may be formed between the first and second circuit patterns 223 and 270. That is, the insulating film 240 may be formed at a position at which the first and second circuit patterns 223 and 270 intersect with each other to electrically insulate the first and second circuit patterns 223 and 270 from each other. The insulating film 240 may be made of a general interlayer insulating material, similar to the insulating layer 210. For example, the insulating film 240 may be made of a prepreg, Ajinomoto Build up Film (ABF), or an epoxy based resin such as FR-4, Bismaleimide Triazine (BT), or the like.

According to another preferred embodiment of the present invention, the second circuit pattern 270 may be formed to intersect with the first circuit pattern 223 over the first circuit pattern 223 when the first and second connection patterns 221 and 222 are electrically connected to each other. Therefore, a design area may be decreased as compared with the prior art in which the first and second circuit patterns 223 and 270 are formed to be spaced apart from each other without being overlapped with each other. In addition, the second circuit pattern 270 is insulated from the first circuit pattern 223 by the insulating film 240, such that a restriction for a position at which the second circuit pattern 270 is formed is decreased, thereby making it possible to increase a degree of freedom in a design. That is, the first circuit layer 220 and the second circuit pattern 270 may be freely connected to each other.

According to another preferred embodiment of the present invention, although not shown, a solder resist for protecting the first circuit layer 220 and the second circuit pattern 270 may be further formed. It is obvious to those skilled in the art that a circuit layer and a solder resist may be further formed on the other surface of the insulating layer 210 as well as one surface of the insulating layer 210 on which the first circuit layer 220 is formed.

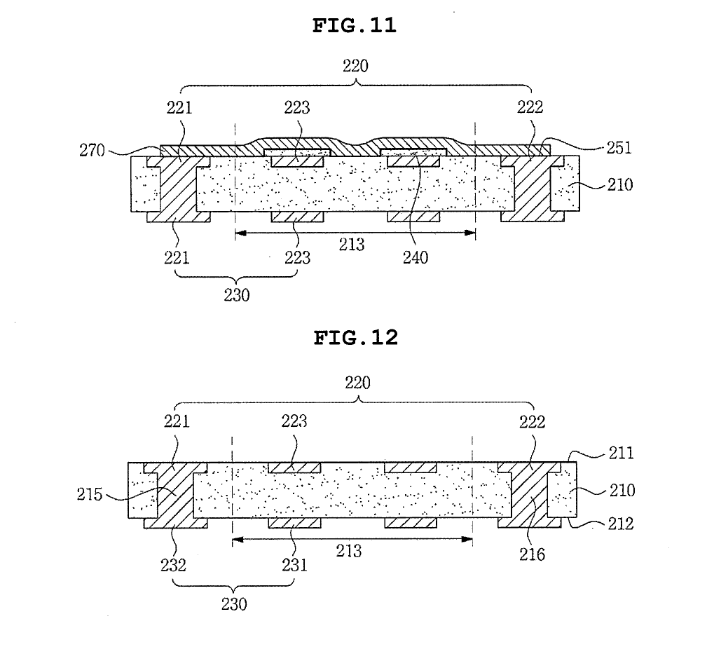

FIG. 11 is a cross-sectional view showing the printed circuit board according to another preferred embodiment of the present invention.

FIG. 11 is a view showing a cross section taken along the line C-D of the printed circuit board 200 shown in FIG. 10.

Referring to FIG. 11, the printed circuit board 200 may include the insulating layer 210, the first circuit layer 220, the second circuit pattern 270, a third circuit layer 230, and the insulating film 240.

The insulating layer 210 may be formed to have first and second surfaces 211 and 212. The insulating layer 210 may be made of a composite polymer resin generally used as an interlayer insulating material. For example, the insulating layer 210 may be made of a prepreg, Ajinomoto Build up Film (ABF), or an epoxy based resin such as FR-4, Bismaleimide Triazine (BT), or the like. In addition, the insulating layer 210 may have a form of a substrate or a film. However, in another preferred embodiment of the present invention, a material and a form of the insulating layer 210 are not limited thereto.

The insulating layer 210 may include an insulating region 213. The insulating region 213 may be formed so that the first circuit layer 220 and the second circuit pattern 270 intersect with each other and be a region in which the first circuit layer 220 and the second circuit pattern 270 are electrically insulated from each other.

The first circuit layer 220 may be formed in the first surface 211 of the insulating layer 210. Here, the first circuit layer 220 may be formed so that the upper surface thereof is exposed to the outside of the first surface 211 of the insulating layer 210. The first circuit layer 220 formed on the insulating layer 210 may include the first connection pattern 221, the second connection pattern 222, and the first circuit pattern 223. Here, the first and second connection patterns 221 and 222 may be components electrically connected to each other by the first circuit pattern 223 or the second circuit pattern 270. As shown, the first and second connection patterns 221 and 222 may be pads of first and second vias 215 and 216 formed in the insulating layer 210, respectively. However, this is only an example. That is, the first and second connection patterns 221 and 222 are not limited to being the pads of the vias. That is, the first and second connection patterns 221 and 222 may be any patterns electrically connected to each other.

The second circuit layer may include the second circuit pattern 270. The second circuit pattern 270 may be formed on the first surface 211 of the first insulating layer 210 and the first circuit pattern 223. Here, the second circuit pattern 270 may be formed so that one end thereof contacts the first connection pattern 221. In addition, the second circuit pattern 270 may be formed so that the other end thereof contacts the second connection pattern 222. The second circuit pattern 270 formed as described above may electrically connect the first and second connection patterns 221 and 222 to each other.

The insulating film 240 may be formed in the insulating region 213 of the insulating layer 210. In addition, the insulating film 240 may be formed between the first and second circuit patterns 223 and 270. The insulating film 240 may be formed at a position at which the first and second circuit patterns 223 and 270 intersect with each other to electrically insulate the first and second circuit patterns 223 and 270 from each other. In this case, the insulating film 240 may be formed to enclose the first circuit pattern 223 in a region in which the second circuit pattern 270 intersects with the first circuit pattern 223. Although not shown in FIG. 11, the insulating film 240 may not be formed on the first circuit pattern 223 in a region in which the first and second circuit patterns 223 and 270 do not intersect with each other.

The insulating film 240 may be made of a general interlayer insulating material, similar to the insulating layer 210. For example, the insulating film 240 may be made of a prepreg, Ajinomoto Build up Film (ABF), or an epoxy based resin such as FR-4, Bismaleimide Triazine (BT), or the like.

The third circuit layer 230 may be formed on the second surface 212 of the insulating layer 210. The third circuit layer 230 may include at least one third circuit pattern 231 and a third connection pattern 232. The third connection pattern 232 may not only be a general circuit pattern, but also be pads of the first and second vias 215 and 216 formed in the insulating layer 210.

According to another preferred embodiment of the present invention, the first circuit layer 220, the second circuit layer, and the third circuit layer 230 may be made of a conductive metal. Here, the conductive metal may be any metal usually used for a circuit pattern, such as copper, nickel, gold, or the like.

Although not shown in FIG. 10, the printed circuit board 200 according to another preferred embodiment of the present invention may further include first and second solder resists 281 and 282. The first and second solder resists 281 and 282 may be formed in order to protect the first circuit layer 220, the second circuit pattern 270, and the third circuit layer 230. In addition, the first and second solder resists 281 and 282 may have opening parts formed therein so that regions for connection to the outside are opened. The first and second solder resists 281 and 282 may be made of a general heat resistant coating material.

Although the case in which the third circuit layer 230 is formed on the second surface 212 of the insulating layer 210 is shown in another preferred embodiment of the present invention, the present invention is not limited thereto. That is, circuit patterns stacked to intersect with each other, such as the first circuit layer 220 and the second circuit pattern 270 formed on the first surface 211 of the insulating layer 210 may also be formed on the second surface 212 of the insulating layer 210.

When the first circuit layer 220 is formed to be buried in the insulating layer 210 according to another preferred embodiment of the present invention, a step between other layers generated due to formation of the insulating film 240 and the second circuit pattern 270 may be minimized. In addition, a thickness of the board may be decreased. Further, the first circuit layer 220 is formed to be buried in the insulating layer 210, such that the second circuit pattern 270 may be stably formed.

FIGS. 12 to 18 are views showing a method for manufacturing a printed circuit board according to another preferred embodiment of the present invention.

Referring to FIG. 12, the insulating layer 210 is provided. The insulating layer 210 may be formed to have the first and second surfaces 211 and 212. The insulating layer 210 may be made of a composite polymer resin generally used as an interlayer insulating material. For example, the insulating layer 210 may be made of a prepreg, Ajinomoto Build up Film (ABF), or an epoxy based resin such as FR-4, Bismaleimide Triazine (BT), or the like. In addition, the insulating layer 210 may have a form of a substrate or a film. However, in another preferred embodiment of the present invention, a material and a form of the insulating layer 210 are not limited thereto.

The insulating layer 210 may include the insulating region 213. The insulating region 213 may be formed so that the first circuit layer 220 and the second circuit pattern 270 intersect with each other and be a region in which the first circuit layer 220 and the second circuit pattern 270 are electrically insulated from each other.

The insulating layer 210 may have the first circuit layer 220 formed in the first surface 211 thereof. Here, the first circuit layer 220 may be formed so that the upper surface thereof is exposed to the outside of the first surface 211 of the insulating layer 210. The first circuit layer 220 formed as described above may include the first connection pattern 221, the second connection pattern 222, and the first circuit pattern 223. Here, the first and second connection patterns 221 and 222 may be components electrically connected to each other by the first circuit pattern 223 or the second circuit pattern 270. As shown, the first and second connection patterns 221 and 222 may be the pads of the first and second vias 215 and 216 formed in the insulating layer 210, respectively. However, this is only an example. That is, the first and second connection patterns 221 and 222 are not limited to being the pads of the vias. That is, the first and second connection patterns 221 and 222 may be any patterns electrically connected to each other.

The insulating layer 210 may have the third circuit layer 230 formed on the second surface 212 thereof. The third circuit layer 230 may include at least one third circuit pattern 231 and the third connection pattern 232. The third connection pattern 232 may not only be a general circuit pattern, but also be pads of the first and second vias 215 and 216 formed in the insulating layer 210.

The first and third circuit layers 220 and 230 may be formed by a semi-additive process (SAP) and a modified semi-additive process (MSAP). However, the first and third circuit layers 220 and 230 are not limited to being formed by the above-mentioned process, but may also be formed by any one of general circuit pattern forming methods.

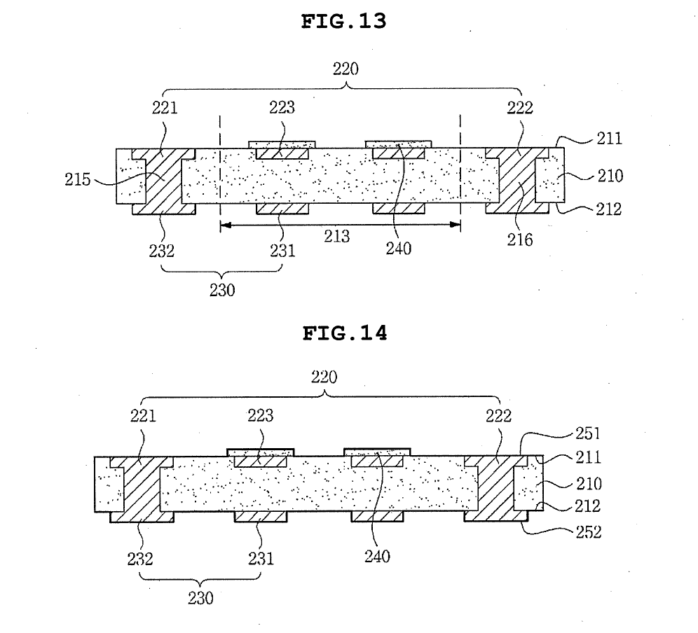

Referring to FIG. 13, the insulating film 240 may be formed on the first circuit pattern 223. The insulating film 240 may be formed in the insulating region 213 of the insulating layer 210. In addition, the insulating film 240 may be formed on the first circuit pattern 223 exposed to the first surface 211 of the insulating layer 210. The insulating film 240 may be made of a general interlayer insulating material, similar to the insulating layer 210. For example, the insulating film 240 may be made of a prepreg, Ajinomoto Build up Film (ABF), or an epoxy based resin such as FR-4, Bismaleimide Triazine (BT), or the like. The insulating film 240 may be formed by an inkjet printing method. That is, the insulating film 240 may be formed by applying a liquid-phase insulating material onto the first circuit pattern 223 using an inkjet. The inkjet printing method as described above is only an example, and a method of forming the insulating film 240 is not limited thereto. The insulating film 240 may be formed by any method of applying a general insulating material as well as the inkjet printing method. Although not shown, the insulating film 240 may not be formed on the first circuit pattern 223 in a region in which the first circuit pattern 223 and a second circuit pattern 270 to be subsequently formed do not intersect with each other.

Referring to FIG. 14, first and second seed layers 251 and 252 may be formed. The first seed layer 251 may be formed on the first surface 211 of the insulating layer 210 and the first circuit layer 220. The second seed layer 252 may be formed on the second surface 212 of the insulating layer 210 and the third circuit layer 230. The first and second seed layers 251 and 252 may be made of a general electrical conductive material used for forming seed layers. For example, the first and second seed layers 251 and 252 may be made of at least one selected from a group consisting of copper, nickel, gold, silver, zinc, palladium, ruthenium, rhodium, lead, and tin. Here, the first seed layer 251 may be formed on the first connection pattern 221, the second connection pattern 222, and the insulating film 240. Here, the first seed layer 251 may be electrically connected to the first and second connection patterns 221 and 222. However, the first seed layer 251 may be in a state in which it is insulated from the first circuit pattern 223 by the insulating film 240.

Although both of the first and second seed layers 251 and 252 are formed in another preferred embodiment of the present invention, the present invention is not limited thereto. That is, an operation of forming the second seed layer 252 may be omitted by selection of those skilled in the art.

The first and second seed layers 251 and 252 may be formed by an electroless plating method. However, a method of forming the first and second seed layers 251 and 252 is not limited to the electroless plating method. The first and second seed layers 251 and 252 may be formed by a general depositing method. For example, the first and second seed layers 251 and 252 may be formed by a dry plating method such as a sputtering method as well as a wet plating method such as the electroless plating method.

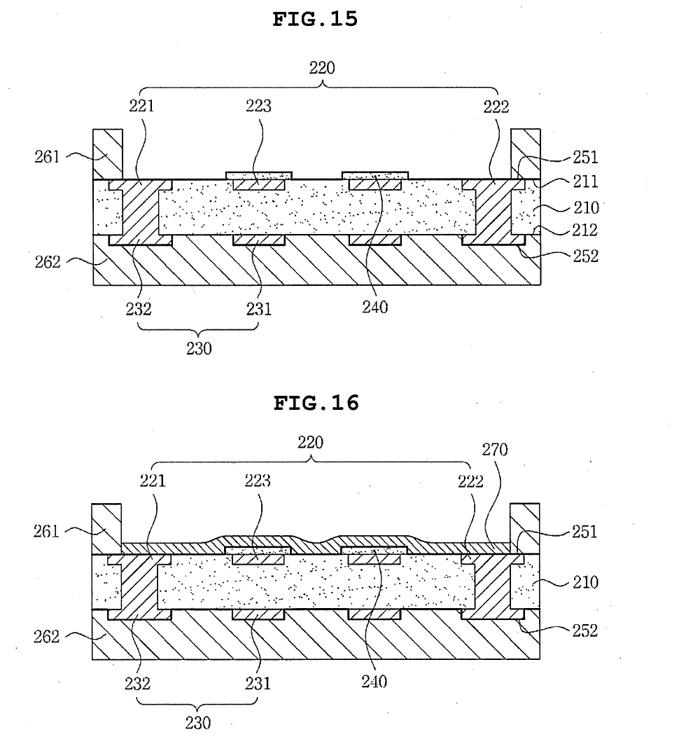

Referring to FIG. 15, a first plating resist 261 may be formed on the first seed layer 251. The first plating resist 261 may have an opening part patterned therein so that a region in which the second circuit pattern 270 is to be formed on the first seed layer 251 is opened.

A second plating resist 262 may be formed on the second seed layer 252. In this configuration, since a circuit pattern is not formed on the second seed layer 252, the second plating resist 262 may be formed on the entire second seed layer 252. As another example, when the circuit pattern is formed on the second seed layer 252, the second plating resist 262 may also have an opening part patterned therein.

Referring to FIG. 16, the second circuit pattern 270, which is a second circuit layer, may be formed. The second circuit pattern 270 may be formed in the opening part of the second plating resist 262 by an electroplating method. Here, the second circuit pattern 270 may be formed by any method of forming a general circuit pattern as well as the electroplating method. The second circuit pattern 270 may be made of a general electrical conductive material used for forming a circuit pattern. For example, the second circuit pattern 270 may be made of at least one selected from a group consisting of copper, nickel, gold, silver, zinc, palladium, ruthenium, rhodium, lead, and tin.

The second circuit pattern 270 formed as described above may be formed on the first circuit layer 220. The second circuit pattern 270 may be formed so that one end thereof contacts the first connection pattern 221. In addition, the second circuit pattern 270 may be formed so that the other end thereof contacts the second connection pattern 222. The second circuit pattern 270 formed as described above may electrically connect the first and second connection patterns 221 and 222 to each other. Here, the second circuit pattern 270 formed on the first circuit pattern 223 may be in a state in which it is insulated from the first circuit pattern 223 by the insulating film 240.

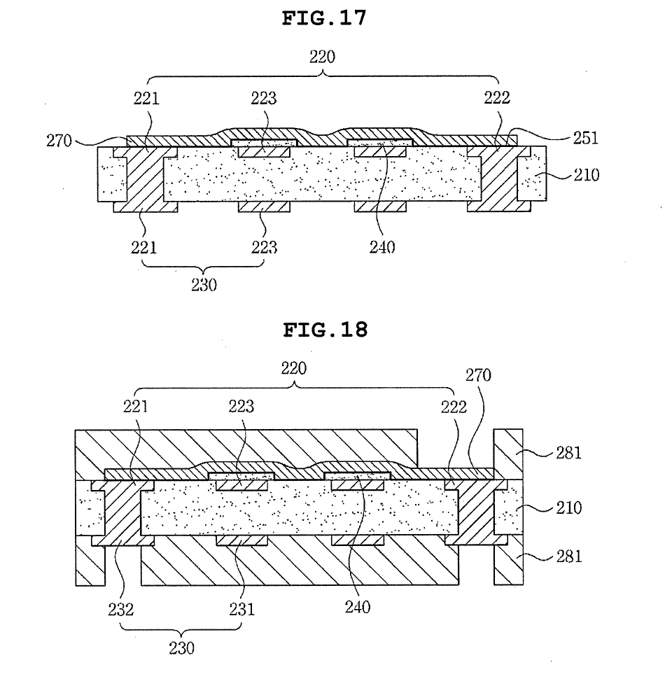

Referring to FIG. 17, the first and second plating resists 261 and 262 may be removed. In addition, the first seed layer 251 exposed by removing the first plating resist 261 may be removed. Further, the first seed layer 252 exposed by removing the second plating resist 262 may be removed. A method of removing the first and second seed layers 251 and 252 is not particularly limited. That is, the first and second seed layers may be removed by a general method well-known in the art. For example, the first and second seed layers 251 and 252 may be removed by a quick etching method using a strong base such as NaOH or KOH. In addition, the first and second seed layers 251 and 252 may be removed by a flash etching method.

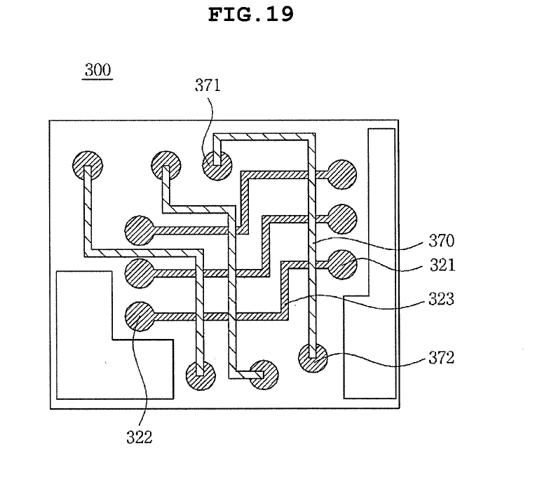

Referring to FIG. 18, the first and second solder resists 281 and 282 may be formed. The first solder resist 281 may be formed in order to protect the first circuit layer 220 and the second circuit pattern 270. The second solder resist 282 may be formed in order to protect the third circuit layer 230. In addition, the first and second solder resists 281 and 282 may have opening parts formed therein so that regions for connection to the outside are opened. The first and second solder resists 281 and 282 may be made of a general heat resistant coating material.

FIG. 19 is a plan view showing a printed circuit board according to the preferred embodiment of the present invention.

Referring to FIG. 19, the printed circuit board 300 may include a first circuit pattern 323 and a second circuit pattern 370.

The first circuit pattern 323 may electrically connect 1-1th and 1-2th connection patterns 321 and 322 to each other. In addition, the second circuit pattern 370 may electrically connect 2-1th and 2-2th connection patterns 371 and 372 to each other. When the second circuit pattern 370 is formed, it may be formed to intersect with the first circuit pattern 323. According to the preferred embodiment of the present invention, an insulating film (not shown) may be formed in a region in which the first and second circuit patterns 323 and 370 intersect with each other. Therefore, even though the first and second circuit patterns 323 and 370 are stacked to intersect with each other by the insulating film 340, the first and second circuit patterns 323 and 370 may be in a state in which they are electrically insulated from each other. As described above, the first and second circuit patterns 323 and 370 are stacked to intersect with each other, thereby making it possible to improve a degree of freedom in a design in forming the circuit pattern. In addition, an amount of area of the board used for forming the circuit pattern may be decreased.

With the printed circuit board and the method for manufacturing the same according to the preferred embodiment of the present invention, the circuit patterns are formed in a two-layer structure, thereby making it possible to decrease a design area.

In addition, with the printed circuit board and the method for manufacturing the same according to the preferred embodiment of the present invention, the first and second circuit patterns are freely connected to each other, thereby making it possible to improve a degree of freedom in a design.

Further, with the printed circuit board and the method for manufacturing the same according to the preferred embodiment of the present invention, the first circuit pattern has a structure in which it is buried in the insulating layer, thereby making it possible to stably form the second circuit pattern over the first circuit pattern.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising:
an insulating layer having first and second surfaces;
a first circuit layer formed on the first surface of the insulating layer and including at least one first circuit pattern;
a second circuit layer formed on the first circuit layer and including at least one second circuit pattern; and
an insulating film formed in an insulating region of the first and second circuit layers.

2. The printed circuit board as set forth in claim 1, wherein the insulating film is formed to enclose the first circuit pattern in the insulating region.

3. The printed circuit board as set forth in claim 1, wherein the first circuit layer is formed on the first surface of the insulating layer.

4. The printed circuit board as set forth in claim 1, wherein the first circuit layer further includes first and second connection patterns.

5. The printed circuit board as set forth in claim 4, wherein the second circuit pattern electrically connects the first and second connection patterns to each other.

6. The printed circuit board as set forth in claim 1, wherein the first circuit layer is buried in the first surface of the insulating layer and is formed so that an upper surface thereof is exposed to the outside of the first surface of the insulating layer.

7. The printed circuit board as set forth in claim 1, further comprising a first solder resist formed on the first surface of the insulating layer, the first circuit layer, and the second circuit layer.

8. The printed circuit board as set forth in claim 1, wherein the second circuit pattern intersects with the first circuit pattern in the insulating region.

9. The printed circuit board as set forth in claim 1, wherein the second circuit pattern has a lower surface contacting the first surface of the insulating layer.

10. The printed circuit board as set forth in claim 1, further comprising a third circuit layer formed on the second surface of the insulating layer and including at least one third circuit pattern.

11. The printed circuit board as set forth in claim 8, further comprising a second solder resist formed on the second surface of the insulating layer and the third circuit layer.

12. The printed circuit board as set forth in claim 1, further comprising at least one internal circuit layer formed in the insulating layer.

13. A printed circuit board comprising:
an insulating layer having first and second surfaces;
a first circuit layer buried in the first surface of the insulating layer, including at least one first circuit pattern, and formed so that an upper surface thereof is exposed to the outside of the first surface of the insulating layer;
a second circuit layer formed on the first circuit layer and including at least one second circuit pattern; and
an insulating film formed in an insulating region of the first and second circuit layers.

14. The printed circuit board as set forth in claim 13, wherein the insulating film is formed to enclose the first circuit pattern in the insulating region.

15. The printed circuit board as set forth in claim 13, wherein the second circuit pattern has a lower surface contacting the first surface of the insulating layer.

16. The printed circuit board as set forth in claim 13, further comprising a third circuit layer formed on the second surface of the insulating layer and including at least one third circuit pattern.

17. A method for manufacturing a printed circuit board, comprising:
preparing an insulating layer having first and second surfaces;
forming a first circuit layer on the first surface of the insulating layer, the first circuit layer including at least one first circuit pattern;
forming an insulating film so as to enclose the first circuit pattern in the insulating region; and
forming a second circuit layer formed on the insulating film, the second circuit layer including at least one second circuit pattern.

18. The method as set forth in claim 17, wherein in the forming of the insulating film, the insulating film is formed over the first circuit pattern on which the second circuit pattern is stacked in the insulating region.

19. The method as set forth in claim 17, wherein in the forming of the insulating film, the insulating film is formed by an inkjet printing method.

20. The method as set forth in claim 17, wherein the forming of the second circuit layer includes:
forming a seed layer on the first surface of the insulating layer and the first circuit layer by an electroless plating method;
forming a plating resist having an opening part formed therein so that a region of the second circuit pattern is opened;
performing electroplating on the opening part to form the second circuit pattern;
removing the plating resist; and
removing the seed layer exposed to the outside by the removed plating resist.

21. The method as set forth in claim 17, wherein the first circuit layer is formed on the first surface of the insulating layer.

22. The method as set forth in claim 17, wherein the first circuit layer is formed to be buried in the first surface of the insulating layer and is formed so that an upper surface thereof is exposed to the outside of the first surface of the insulating layer.

23. The method as set forth in claim 17, further comprising, after the forming of the second circuit layer, forming a first solder resist on the first surface of the insulating layer, the first circuit layer, and the second circuit layer.

24. The method as set forth in claim 17, further comprising forming a third circuit layer on the second surface of the insulating layer at the time of forming the first circuit layer, the third circuit layer including a third circuit pattern.

25. The method as set forth in claim 17, further comprising, after the forming of the third circuit layer, forming a second solder resist on the second surface of the insulating layer and beneath the third circuit layer.

26. The method as set forth in claim 17, wherein in the forming of the first circuit layer, the first circuit layer further includes first and second connection patterns.

27. The method as set forth in claim 17, wherein in the forming of the second circuit pattern, the second circuit pattern is formed to electrically connect the first and second connection patterns to each other.
